(19) United States
(12) Patent Application Publication
(10) Pub. No.: US 2024/0039474 A1
(43) Pub. Date: Feb. 1, 2024

(54) ORGANIC SOLAR CELL FOR CURRENT-VOLTAGE TEST AND PREPARATION METHOD THEREOF

(71) Applicant: Beijing Institute of Technology, Beijing (CN)

(72) Inventors: Shanshan Wang, Beijing (CN); Qiaoshi An, Beijing (CN); Jianxin Du, Beijing (CN); Shaochun Peng, Beijing (CN); Jiatao Zhang, Beijing (CN); Peifeng Gao, Beijing (CN); Jianbing Gao, Beijing (CN); Mengyun Jiang, Beijing (CN); Peng Mao, Beijing (CN); Qiwen Yang, Beijing (CN)

(21) Appl. No.: 18/377,993

(22) Filed: Oct. 9, 2023

(30) Foreign Application Priority Data
Jul. 25, 2023 (CN) 202310914917.1

(51) Int. Cl. H02S 50/10; H10K 30/30; H10K 30/40; H10K 30/50; H10K 30/82; H10K 71/12; H10K 71/60

(52) U.S. Cl. CPC H02S 50/10; H10K 30/30; H10K 30/40; H10K 30/50; H10K 30/82; H10K 71/12; H10K 71/60; H10K 2102/103

(57) ABSTRACT

The present invention relates to an organic solar cell for a current-voltage test and a preparation method thereof. The disclosed organic solar cell for the current-voltage test comprises a substrate with a preset ITO pattern, wherein ITO on the substrate with the preset ITO pattern is used as the anode layer, and a hole transport layer, an active layer, an electron transport layer and a cathode layer are stacked successively to form a solar cell. A plurality of cell positions are designed on the substrate in the present invention. Each cell has an independent cathode test site and an anode test site. The distance between the test site of each cell and the cell is kept the same and the distance is short enough; and the cells are distributed evenly on the substrate discretely. The present invention has high substrate utilization rate, high data accuracy and good parallelism.

### TECHNICAL FIELD

The present invention belongs to the technical field of detection of organic solar cells, and particularly relates to an organic solar cell for a current-voltage test and a preparation method thereof.

### BACKGROUND

Organic solar cells (OSCs) are a kind of potential green photoelectric conversion technology, and have a series of advantages of low processing and preparation cost, light weight, flexibility, translucency, printing, large area production, integration of power generation and wearing, integration of practicability and beauty, facing of further important industries and integrated equipment. The power conversion efficiency (PCE) of OSCs is an important parameter to evaluate the quality of the cell, and is in direct proportion to the product of open-circuit voltage (V_{OC}), short-circuit current density (J_{SC}) and fill factor (FF). The contact resistance between an electrode and an active layer belongs to the series resistance. Therefore, we hope that the series resistance of the solar cell is as small as possible, so that the photovoltage that is divided by the series resistance when the cell is operated is small, and the internal consumption itself will be small. The series resistance of the organic solar cell has a direct effect on the short-circuit current density (J_{SC}), the open-circuit voltage (V_{OC}) and the fill factor (FF) of the cell.

Domestic and foreign research and development teams most commonly use the cells in “in-line” distribution. All the cells share one ITO electrode. Because the conductivity of ITO is low and the efficiency of the cells decreases as the distance between a probe and the cells becomes longer, the usable efficiency of the cells is reduced. Secondly, a plurality of effective cells on the traditional substrate are distributed in an “in-line” type, and are located in the midline position of the substrate, and the distribution of effective test units is relatively simple, which may increase the accidental error of the test to some extent. When each unit of the traditional “in-line” substrates conducts a test, one ITO electrode is shared, so the relative positions of each unit with a positive electrode and a negative electrode of the probe are different, causing the decrease of the PCE of the cells as the distance between the probe and the cells becomes longer, resulting in measurement errors. When one unit conducts the test, the test current has an effect on other units, causing the decrease of the PCE of the cells of other units. Therefore, the accuracy of the experimental data is reduced, and meanwhile, the parallelism of the experimental data is not high, and the accuracy deviation is large.

Therefore, the technical problem to be urgently solved in the field is to develop a test cell with high operability, high efficiency, good parallelism and high accuracy.

### SUMMARY

In view of this, the present invention provides a test cell with high operability, high efficiency, good parallelism and high accuracy. By changing the “in-line” distribution mode of the traditional cell, each cell is designed to have an independent electrode to avoid a test error caused by a shared electrode. The distances between test sites and the cells are the same and short enough to avoid the mutual influence between the cells during the test and improve the test efficiency. The discrete uniform distribution of the cells changes the “in-line” distribution mode of the traditional cell, improves the efficiency and accuracy of the cell test, facilitates the assessment of the uniformity of active layer film formation in a large area, and lays a foundation for the preparation of a large area battery system.

To achieve the above purpose, the first purpose of the present invention is to provide an organic solar cell for a current-voltage test. The present invention adopts the following technical solution:

An organic solar cell for a current-voltage test, comprising a substrate S0, an anode layer S1, a hole transport layer S2, an active layer S3, an electron transport layer S4 and an electrode coating S5 successively, wherein the substrate S0 has a preset ITO pattern.

Preferably, the substrate S0 is made of a square glass material.

Further preferably, the ITO coating of the substrate S0 with the preset ITO pattern is the anode layer S1, and the regions of the ITO coating are rectangles N1 with long sides of L1 and wide sides of M1, and distributed evenly in a plurality of positions on the surface of the substrate discretely.

It is worth noting that the cells are distributed in an “in-line” type. All the cells share one ITO electrode. Because the conductivity of ITO is low and the PCE of the cells decreases as the distance between a probe and the cells becomes longer, the usable efficiency of the cells is reduced. Secondly, a plurality of effective cells on the traditional substrate are distributed in an “in-line” type, and located in the midline position of the substrate. The distribution of effective test units is relatively simple, which may increase the accidental error of the test to some extent. When each unit of the traditional “in-line” cells conducts a test, one ITO electrode is shared, so the relative positions of each unit with a positive electrode and a negative electrode of the probe are different, causing the decrease of the PCE of the cells as the distance between the probe and the cells becomes longer, resulting in measurement errors. When one unit conducts the test, the test current has an effect on other units, causing the decrease of the PCE of the cells of other units. Therefore, the accuracy of the experimental data is reduced, and meanwhile, the parallelism of the experimental data is not high, and the accuracy deviation is large.

The present invention changes the “in-line” distribution mode of the traditional cell through the patterned design of the ITO coating; each cell has independent electrodes, and the test sites have the same distance from the cells to avoid test errors caused by the shared electrode and ITO resistance; and the substrate utilization rate is high and the test data parallelism is good.

Further preferably, rectangular regions N2 without the hole transport layer S2, the active layer S3 and the electron transport layer S4 coating are arranged at a parallel edge of the substrate S0 perpendicular to the direction of ITO to expose the ITO coating; and the rectangular regions N2 without the coating are perpendicular to the long side L1 of the region N1 of the rectangle ITO and parallel to the wide side M1 of the region N1 of the rectangle ITO, and are in one-to-one correspondence with the positions of current-voltage test electrodes.

In order for the hole transport layer to effectively block electrons and help holes to be successfully collected by ITO, preferably, the hole transport layer S2 is PEDOT: PSS.

Preferably, the active layer S3 comprises a donor material and an acceptor material, and the donor material comprises PM6, D18 or B1; and the acceptor material comprises Y6, BO-4C1, BTP-eC9, L8-BO or OSe. Therefore, the active layer material of the present invention is prepared by blending the donor material and the acceptor material. Under the condition of light irradiation, the active layer material may capture photons and absorb the energy of the photons to generate electron-hole pairs. The electrons and the holes eventually migrate to the corresponding electrodes and are collected, to form a circuit path.

Preferably, the electron transport layer S4 is PDIN, PDINN or PNDIT-F3N. The electron transport layer disclosed by the present invention can also improve the electron transport efficiency while blocking the holes.

Further preferably, the electrode coating S5 comprises L-shaped regions N3 and rectangular regions N4 which are distributed evenly on the surface of the substrate discretely, and the rectangular regions N4 are in one-to-one correspondence with the rectangular regions N1 of the anode layer S1; and

the long side L4 of the rectangular region N4 is less than the long side L1 of the rectangular region N1, and the wide side M4 of the rectangular region N4 is equal to the wide side M1 of the rectangular region N1; the L-shaped region N3 is composed of a rectangle N31 and a rectangle N32, the

wide side M4 of the rectangular region N4≤the long side L311 of N31≤the long side L321 of N32, and the wide side M311 of N31 is equal to the wide side M4 of the rectangular region N4; the wide side M321 of N32≤the wide side M1 of the rectangular region N1, and the long side L4 of the rectangular region N4≤the long side L321 of N32≤the long side Ll of the rectangular region N1.

Further preferably, the L-shaped regions N3 and the rectangular regions N4 have opposite polarities; and

the L-shaped regions N3 are cathode layers of the organic solar cell; and the rectangular regions N4 and the ITO are conducted and jointly used as anodes of the organic solar cell.

Further preferably, the long side L2 of the rectangular region N2 without the coating is equal to the side length of the substrate S0, and the wide side M2 of the rectangular region N2 without the coating≤the long side L4 of the rectangle N4.

Further preferably, an arrangement region Q1 of the cell is a region where the anode layer ITO S1, the hole transport layer S2, the active layer S3, the electron transport layer S4 and the cathode layer N3 on the substrate S0 with the preset ITO pattern are overlapped.

It is worth noting that through the arrangement region Q1 in the present invention, the distribution of the cells on the substrate is even and dispersed, rather than concentrated in a single line, so as to facilitate the assessment of the film formation uniformity of an active layer preparation process and improve the accuracy of the cell test.

It is worth noting that an overlapping region Q2 of the rectangular regions N2 with the ITO coating S1 of the substrate S0 with the preset ITO pattern and the rectangles N4 in the silver electrode coating S5 is used as a hole path for the main purpose of hole transport generated by illumination of the active layer S3 in Q1. Holes are generated in the active layer S3 in Q1, pass through the hole transport layer S2 in Q1 to reach the ITO coating S1 in Q1, and are received by the positive electrode of a current-voltage test device through Q2. An overlapping region Q3 of the rectangular regions N2 without the coating with the L-shaped N3 in the silver electrode coating S5 is used as an electron path for the main purpose of electron transport generated by illumination of the active layer S3 in Q 1 . The active layer S3 in Q1 generates electrons, and the electrons pass through the electron transport layer S4 in Q1 to reach the L-shaped region Q3 in the silver electrode coating S5, and are received by the negative electrode of the current-voltage test device through Q3.

The second purpose of the present invention is to provide a preparation method of the organic solar cell for the current-voltage test.

A preparation method of the organic solar cell for the current-voltage test comprises the following steps:

I. cleaning and treating the substrate S0 with the preset ITO pattern by an ultrasonic cleaning method and an ultraviolet ozone method;

II. preparing the hole transport layer S2, the active layer S3 and the electron transport layer S4 successively on the surface of the substrate S0 by a spin-coating method, wherein spin-coating area is the size of the substrate S0;

III. removing the spin-coating coating from the parallel edge of the surface of the substrate S0 perpendicular to the direction of ITO to the interior of the surface of the substrate S0 to form rectangular regions N2 without the spin-coating coating;

IV. evaporating a metallic silver electrode S5 on the substrate through a vacuum evaporation method of the substrate obtained in step III combined with a mask plate with a preset pattern to obtain the organic solar cell for the current-voltage test. It is worth noting that the ultrasonic cleaning in step I is mainly to remove dust,

grease and impurities on the substrate; and the use of ultraviolet ozone treatment is mainly conducive to optimizing the surface physical properties of ITO, such as work function, surface energy, conductivity, etc.

Compared with the prior art, the organic solar cell for the current-voltage test disclosed by the present invention comprises the substrate with the preset ITO pattern, wherein the ITO on the substrate with the preset ITO pattern is used as the anode layer, and the hole transport layer, the active layer, the electron transport layer and the cathode layer are stacked successively to form a solar cell. Firstly, the substrate with the preset ITO pattern is cleaned and treated; secondly, the hole transport layer, the active layer and the electron transport layer are spin-coated successively on the substrate with the preset ITO pattern; then, a certain width of the coating is scraped into the substrate at a certain distance from two parallel sides perpendicular to the direction of the ITO and perpendicular to the long side Ll of the rectangular ITO S1 and parallel to the wide side M1 to expose the ITO layer, which corresponds to the position of the current-voltage test electrode one by one; and finally, the cathode layer is evaporated on the substrate by a vacuum evaporation method combined with the mask plate with the preset pattern. A plurality of cell positions are designed on the substrate in the present invention. Each cell has an independent cathode test site and an anode test site to avoid the mutual influence between the cells during the test and improve the test efficiency. The distance between the test site of each cell and the cell is kept the same and the distance is short enough; and the cells are distributed evenly on the substrate discretely. The present invention has high substrate utilization rate, high data accuracy and good parallelism, greatly improves the cell test efficiency and facilitates the assessment of the uniformity of active layer film formation in a large area.

### DESCRIPTION OF DRAWINGS

To more clearly describe the technical solutions in the embodiments of the present invention or in the prior art, the drawings required to be used in the description of the embodiments or the prior art will be simply presented below. Apparently, the drawings in the following description are merely the embodiments of the present invention, and for those ordinary skilled in the art, other drawings can also be obtained according to the provided drawings without contributing creative labor.

FIG. 1 is a schematic diagram of a substrate S0 with a preset ITO pattern and an anode layer Si in the present invention.

FIG. 2 is a schematic diagram of a region N2 without coating on a substrate with a preset ITO pattern in the present invention.

FIG. 3 is a schematic diagram of an electrode coating S5 in the present invention.

FIG. 4 is a schematic diagram of an arrangement region Q1 of cells in the present invention.

FIG. 5 is a schematic diagram of a region N2 without coating on a solar cell in the present invention.

FIG. 6 is a three-dimensional schematic diagram of an organic solar cell for a current-voltage test in the present invention.

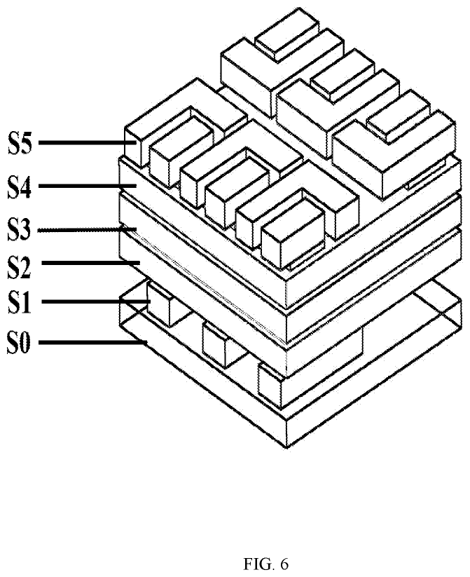

FIG. 7 is an axial three-dimensional schematic diagram of an organic solar cell for a current-voltage test in the present invention.

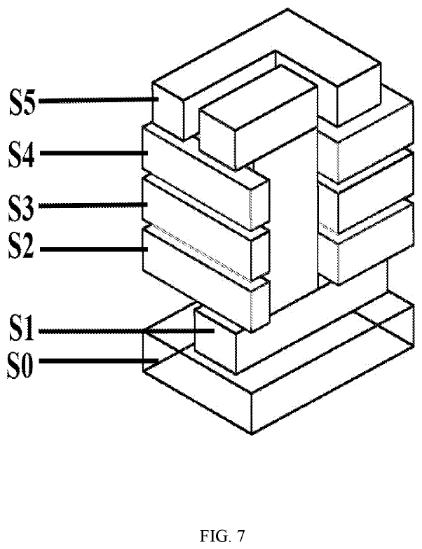

FIG. 8 is another axial three-dimensional schematic diagram of an organic solar cell for a current-voltage test in the present invention.

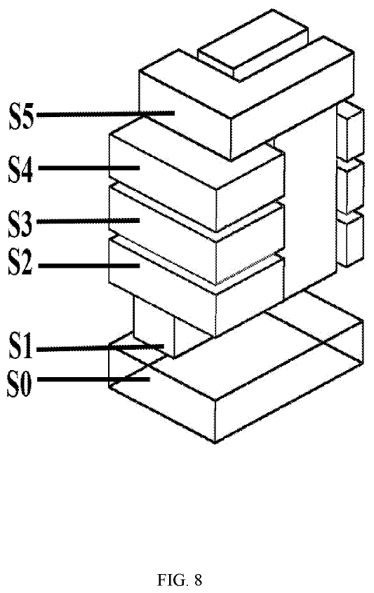

### DETAILED DESCRIPTION

The technical solutions in the embodiments of the present invention will be clearly and fully described below in combination with the drawings. Apparently, the described embodiments are merely part of the embodiments of the present invention, not all of the embodiments. Based on the embodiments in the present invention, all other embodiments obtained by those ordinary skilled in the art without contributing creative labor will belong to the protection scope of the present invention.

Each embodiment in the description is described in a progressive way. The difference of each embodiment from each other is the focus of explanation. The same and similar parts among all of the embodiments can be referred to each other. For a device disclosed by the embodiments, because the device corresponds to a method disclosed by the embodiments, the device is simply described. Refer to the description of the method part for the related part.

### Embodiment 1

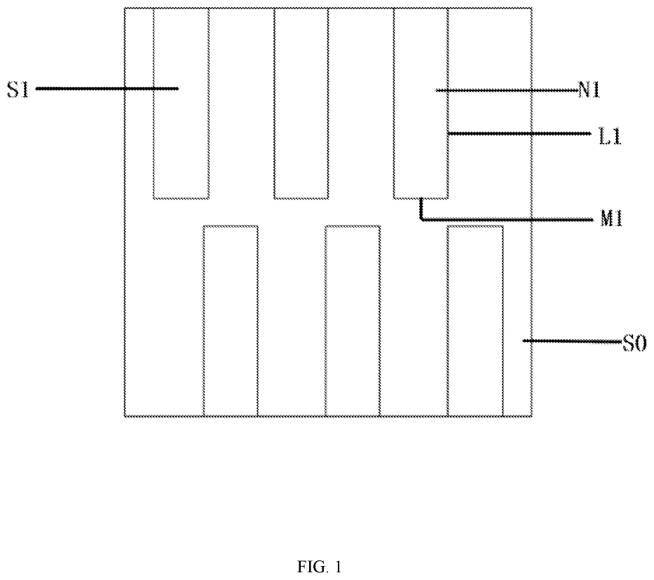

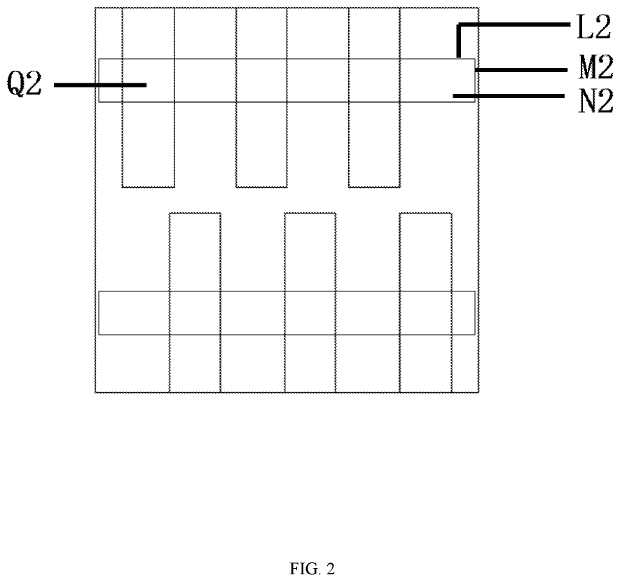

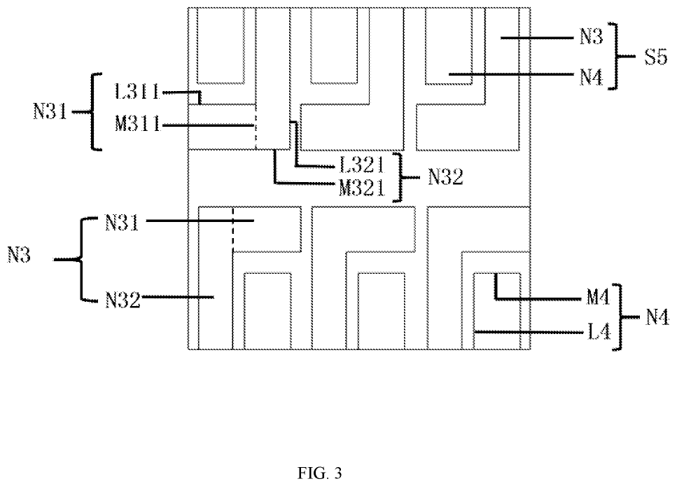

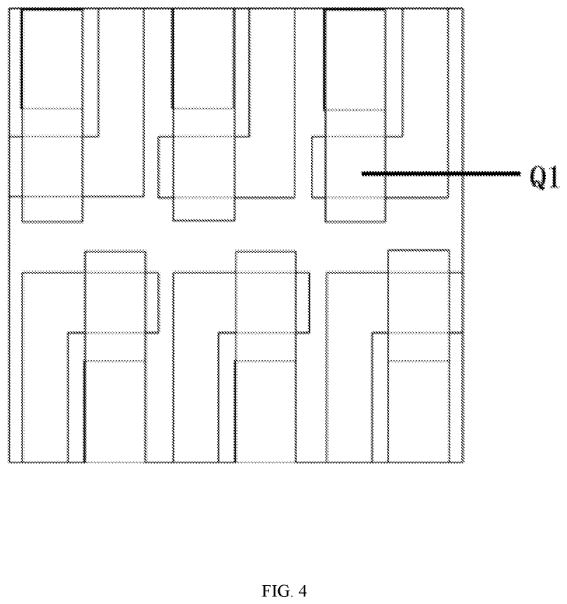

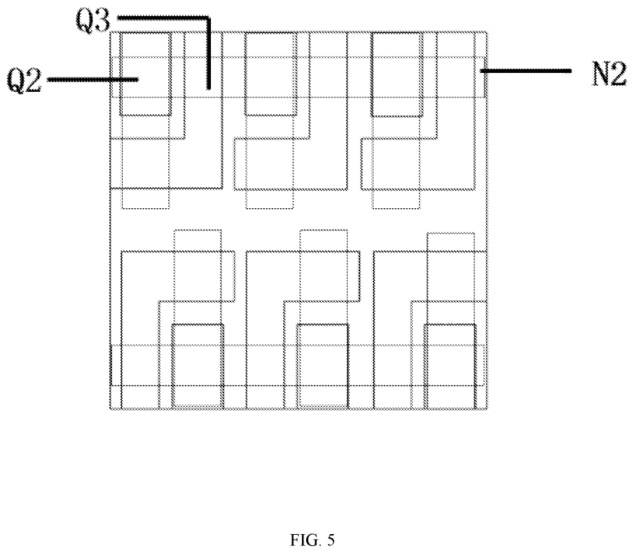

A substrate S0 with a preset ITO pattern (as shown in FIG. 1) is cleaned and treated by an ultrasonic cleaning method and an ultraviolet ozone method. Specifically, firstly, the substrate is ultrasonically cleaned in a cleaning agent for 2 h and rinsed with deionized water for 5 times; then the substrate is ultrasonically cleaned with deionized water for 3 times, and finally put into anhydrous ethanol for ultrasonic cleaning for 15 min. Then, the anhydrous ethanol attached to the surface of the cleaned substrate is blown dry with a nitrogen gun, and then the substrate is put into UVO for ozone treatment for 15 min. The substrate with the preset ITO pattern is placed on a spin coater to spin coating the hole transport layer; the material is PEDOT: PSS; the spin coating time is 40 s, the rotational speed is 5000 RPM, and the thickness of the hole transport layer is about 30 nm. Then, the substrate is placed on a heating table at 150° C. and thermally annealed for 10 min. The annealed substrate is transferred to a glove box filled with high purity nitrogen and cooled to room temperature. An active layer S3 is spin-coated on the obtained substrate by the spin coater. A donor material is PM6 and an acceptor material is BO-4C1, which are weighed by a mass ratio of 1:1.2. A CB solvent is used for dissolving at the donor concentration of 10 mg/mL, and the materials are heated and stirred at 75° C. on a magnetic heating table for 3 h. The spin coating time is 30 s, the rotational speed is 3000 RPM, and the film thickness is 110 nm. The obtained substrate is placed on the heating table and thermally annealed at 80° C. for 10 min. Then, the obtained substrate is placed on the spin coater to spin coating the electron transport layer S4; the material is PDIN; the spin coating time is 30 s, and the rotational speed is 5000 RPM. The thickness is about 100 nm. A certain width of the coating is scraped into the substrate at a certain distance from two parallel sides perpendicular to the long side L1 of the rectangular ITO S1 and parallel to the wide side M1 to expose the ITO layer (as shown in FIG. 2 and FIG. 5), which corresponds to the position of the current-voltage test electrode one by one. A metallic silver electrode S5 (as shown in FIG. 3) is evaporated on the substrate through a vacuum evaporation method of the substrate combined with a mask plate with a preset pattern. A region where the anode layer ITO Si, the hole transport layer S2, the active layer S3, the electron transport layer S4 and the cathode layer N4 on the substrate S0 with the preset ITO pattern are overlapped is a cell, and the cell region is a square Q1 (as shown in FIG. 4). Current-voltage curve acquisition is conducted for the formed Glass/ITO/PEDOT:PSS/PM6:BO-4C1/ PDIN/ Ag organic solar cell. The results are shown in Table 1.

In order to better illustrate the embodiment, the traditional “in-line” cell and a matched test fixture are used to measure the cell performance parameters of the same system, as shown in Table 2.

TABLE 1
Cell Performance Parameters of PM6:BO—4Cl
System Based on the Test Substrate

| | J_{SC} | V_{OC} | FF | PCE |
|---|---|---|---|---|
| PM6:BO—4Cl | [mA cm⁻²] | [V] | [%] | [%] |
| 1 | 26.41 | 0.852 | 77.95 | 17.54 |
| 2 | 26.29 | 0.852 | 78.61 | 17.61 |
| 3 | 26.44 | 0.851 | 78.00 | 17.55 |
| 4 | 26.25 | 0.853 | 77.83 | 17.42 |
| 5 | 26.37 | 0.853 | 78.12 | 17.57 |
| 6 | 26.34 | 0.854 | 78.05 | 17.56 |

(Note:
the data in each table comes from an effective test unit on the same substrate)

TABLE 2
Cell Performance Parameters of PM6:BO—4Cl System Based
on Traditional “In-Line” ITO Substrate

| | J_{SC} | V_{OC} | FF | PCE |
|---|---|---|---|---|
| PM6:BO—4Cl | [mA cm⁻²] | [V] | [%] | [%] |
| 1 | 26.39 | 0.851 | 78.45 | 17.61 |
| 2 | 26.18 | 0.853 | 77.29 | 17.26 |
| 3 | 26.09 | 0.851 | 75.76 | 16.82 |
| 4 | 25.88 | 0.853 | 73.18 | 16.16 |

(Note:
the data in each table comes from an effective test unit on the same substrate)

It can be seen from Table 1 that six groups of data values from the same substrate are relatively consistent. The maximum PCE value of the six groups of data is 17.61%, the minimum value is 17.42%, the average PCE is 17.54%, and the standard deviation is 0.059. It can be seen from Table 2 that in four groups of data from the same substrate, the maximum PCE is 17.61%, the minimum PCE is 16.16%, the average PCE of the four groups of data is 16.16% and the standard deviation is 0.54. It can be seen that the preparation efficiency and experimental success rate of the cell based on the substrate of the present invention are greatly improved, and the data are accurate, stable and good in parallelism.

Embodiment 2

A substrate S0 with a preset ITO pattern (as shown in FIG. 1) is cleaned and treated by an ultrasonic cleaning method and an ultraviolet ozone method. Specifically, firstly, the substrate is ultrasonically cleaned in a cleaning agent for 2 h and rinsed with deionized water for 5 times; then the substrate is ultrasonically cleaned with deionized water for 3 times, and finally put into anhydrous ethanol for ultrasonic cleaning for 15 min. Then, the anhydrous ethanol attached to the surface of the cleaned substrate is blown dry with a nitrogen gun, and then the substrate is put into UVO for ozone treatment for 15 min. The substrate with the preset ITO pattern is placed on a spin coater to spin coating the hole transport layer; the material is PEDOT: PSS; the spin coating time is 35 s, the rotational speed is 5000 RPM, and the thickness of the hole transport layer is about 30 nm. Then, the substrate is placed on a heating table at 150° C. and thermally annealed for 15 min. The annealed substrate is transferred to a glove box filled with high purity nitrogen and cooled to room temperature. An active layer S3 is spin-coated on the obtained substrate by the spin coater. A donor material is PM1 and an acceptor material is OSe, which are weighed by a mass ratio of 1:1.25. A CF solvent is used for dissolving at the donor concentration of 8.8 mg/mL, and the materials are heated and stirred at 45° C. on a magnetic heating table for 2.5 h. The spin coating time is 30 s, the rotational speed is 3000 RPM, and the film thickness is 110 nm. The obtained substrate is placed on the heating table and thermally annealed at 80° C. for 5 min. Then, the obtained substrate is placed on the spin coater to spin coating the electron transport layer S4; the material is PDIN; the spin coating time is 30 s, and the rotational speed is 6000 RPM. The thickness is about 100 nm. A certain width of the coating is scraped into the substrate at a certain distance from two parallel sides perpendicular to the long side L1 of the rectangular ITO S1 and parallel to the wide side M1 to expose the ITO layer (as shown in FIG. 2 and FIG. 5), which corresponds to the position of the current-voltage test electrode one by one. A metallic silver electrode S5 (as shown in FIG. 3) is evaporated on the substrate through a vacuum evaporation method of the substrate combined with a mask plate with a preset pattern. A region where the anode layer ITO Si, the hole transport layer S2, the active layer S3, the electron transport layer S4 and the cathode layer N4 on the substrate S0 with the preset ITO pattern are overlapped is a cell, and the cell region is a square Q1 (as shown in FIG. 4). Current-voltage curve acquisition is conducted for the formed Glass/ITO/PEDOT:PSS/PM1:0Se/PDIN/Ag organic solar cell. The results are shown in Table 3.

In order to better illustrate the embodiment, the traditional “in-line” cell and a matched test fixture are used to measure the cell performance parameters of the same system, as shown in Table 4.

TABLE 3
Cell Performance Parameters of PM1:OSe
System Based on the Test Substrate

| | J_{SC} | V_{OC} | FF | PCE |
|---|---|---|---|---|
| PM1:OSe | [mA cm⁻²] | [V] | [%] | [%] |
| 1 | 25.96 | 0.870 | 75.28 | 17.00 |
| 2 | 25.92 | 0.870 | 76.95 | 17.35 |
| 3 | 25.77 | 0.869 | 76.33 | 17.09 |
| 4 | 25.71 | 0.869 | 77.08 | 17.22 |
| 5 | 25.91 | 0.868 | 76.90 | 17.29 |
| 6 | 25.95 | 0.867 | 75.60 | 17.01 |

(Note:
the data in each table comes from an effective test unit on the same substrate)

TABLE 4
Cell Performance Parameters of PM1:OSe System Based
on Traditional “In-Line” ITO Substrate

| | J_{SC} | V_{OC} | FF | PCE |
|---|---|---|---|---|
| PM1:OSe | [mA cm⁻²] | [V] | [%] | [%] |
| 1 | 25.99 | 0.867 | 76.32 | 17.20 |
| 2 | 25.97 | 0.866 | 74.80 | 16.82 |
| 3 | 25.94 | 0.865 | 73.31 | 16.45 |
| 4 | 25.71 | 0.864 | 71.40 | 15.86 |

(Note:
the data in each table comes from an effective test unit on the same substrate)

It can be seen from Table 3 that six groups of data values from the same substrate are relatively consistent. The maximum PCE value of the six groups of data is 17.35%, the minimum value is 17.00%, the average PCE is 17.16%, and the standard deviation is 0.148.

It can be seen from Table 4 that in four groups of data from the same substrate, the maximum PCE is 17.20%, the minimum PCE is 15.86%, the average PCE of the four groups of data is 16.58% and the standard deviation is 0.571. It can be seen that the preparation efficiency and experimental success rate of the cell based on the substrate of the present invention are greatly improved, and the data are accurate, stable and good in parallelism.

The above description of the disclosed embodiments enables those skilled in the art to realize or use the present invention. Many modifications to these embodiments will be apparent to those skilled in the art. The general principle defined herein can be realized in other embodiments without departing from the spirit or scope of the present invention. Therefore, the present invention will not be limited to these embodiments shown herein, but will conform to the widest scope consistent with the principle and novel features disclosed herein.

What is claimed is:

1. An organic solar cell for a current-voltage test, comprising a substrate S0, an anode layer S1, a hole transport layer S2, an active layer S3, an electron transport layer S4 and an electrode coating S5 successively, wherein the substrate S0 has a preset ITO pattern.

2. The organic solar cell for the current-voltage test according to claim 1, wherein the substrate S0 is made of a square glass material.

3. The organic solar cell for the current-voltage test according to claim 2, wherein the ITO coating of the substrate S0 with the preset ITO pattern is the anode layer Si, and the regions of the ITO coating are a plurality of rectangles N1 with long sides of L1 and wide sides of M1, and distributed evenly in a plurality of positions on the surface of the substrate discretely.

4. The organic solar cell for the current-voltage test according to claim 3, wherein rectangular regions N2 without the hole transport layer S2, the active layer S3 and the electron transport layer S4 coating are arranged at a parallel edge of the substrate S0 perpendicular to the direction of ITO to expose the ITO coating; and the rectangular regions N2 without the coating are perpendicular to the long side L1 of the region N1 of the rectangle ITO and parallel to the wide side M1 of the region N1 of the rectangle ITO, and are in one-to-one correspondence with the positions of current-voltage test electrodes.

5. The organic solar cell for the current-voltage test according to claim 1, wherein the hole transport layer S2 is PEDOT: PSS.

6. The organic solar cell for the current-voltage test according to claim 1, wherein the active layer S3 comprises a donor material and an acceptor material, and the donor material comprises PM6, D18 or B1; and the acceptor material comprises Y6, BO-4C1, BTP-eC9, L8-BO or OSe.

7. The organic solar cell for the current-voltage test according to claim 1, wherein the electron transport layer S4 is PDIN, PDINN or PNDIT-F3N.

8. The organic solar cell for the current-voltage test according to claim 4, wherein the electrode coating S5 comprises L-shaped regions N3 and rectangular regions N4 which are distributed evenly on the surface of the substrate discretely, and the rectangular regions N4 are in one-to-one correspondence with the rectangular regions N1 of the anode layer Si; and
the long side L4 of the rectangular region N4 is less than the long side L1 of the rectangular region N1, and the wide side M4 of the rectangular region N4 is equal to the wide side M1 of the rectangular region N1;
the L-shaped region N3 is composed of a rectangle N31 and a rectangle N32, the wide side M4 of the rectangular region N4<the long side L311 of N31≤the long side L321 of N32, and the wide side M311 of N31 is equal to the wide side M4 of the rectangular region N4; the wide side M321 of N32≤the wide side M1 of the rectangular region N1, and the long side L4 of the rectangular region N4<the long side L321 of N32≤the long side Ll of the rectangular region N1.

9. The organic solar cell for the current-voltage test according to claim 8, wherein the L-shaped regions N3 and the rectangular regions N4 have opposite polarities; and
the L-shaped regions N3 are cathode layers of the organic solar cell; and the rectangular regions N4 and the ITO are conducted and jointly used as anodes of the organic solar cell.

10. The organic solar cell for the current-voltage test according to claim 8, wherein the long side L2 of the rectangular region N2 without the coating is equal to the side length of the substrate S0, and the wide side M2 of the rectangular region N2 without the coating≤the long side L4 of the rectangle N4.

11. The organic solar cell for the current-voltage test according to claim 9, wherein an arrangement region Q1 of the cell is a region where the anode layer ITO S1, the hole transport layer S2, the active layer S3, the electron transport layer S4 and the cathode layer N3 on the substrate S0 with the preset ITO pattern are overlapped.

12. A preparation method of the organic solar cell for the current-voltage test in claim 1, comprising the following steps:
I. cleaning and treating the substrate S0 with the preset ITO pattern by an ultrasonic cleaning method and an ultraviolet ozone method;
II. preparing the hole transport layer S2, the active layer S3 and the electron transport layer S4 successively on the surface of the substrate S0 by a spin-coating method, wherein spin-coating area is the size of the substrate S0;
III. removing the spin-coating coating from the parallel edge of the surface of the substrate S0 perpendicular to the direction of ITO to the interior of the surface of the substrate S0 to form rectangular regions N2 without the spin-coating coating;
IV. evaporating a metallic silver electrode S5 on the substrate through a vacuum evaporation method of the substrate obtained in step III combined with a mask plate with a preset pattern to obtain the organic solar cell for the current-voltage test.
